(19) United States
(12) Patent Application Publication
(10) Pub. No.: US 2026/0092637 A1
(43) Pub. Date: Apr. 2, 2026

(54) BUCKLING STRUCTURE

(71) Applicant: FIVEGRAND INTERNATIONAL CO., LTD., New Taipei City (TW)

(72) Inventor: TING-JUI WANG, New Taipei City (TW)

(73) Assignee: FIVEGRAND INTERNATIONAL CO., LTD., New Taipei City (TW)

(21) Appl. No.: 19/216,749

(22) Filed: May 23, 2025

(30) Foreign Application Priority Data
Oct. 1, 2024 (TW) 113137572

(51) Int. Cl. F16F 15/04

(52) U.S. Cl. CPC F16F 15/04; F16F 2230/0029; F16F 2238/026

(57) ABSTRACT

A buckling structure and a buckling method thereof are introduced. The buckling structure includes an intermediary and an actuator. The actuator is movably or fixedly arranged on the intermediary. The actuator includes a body portion and an operating portion. The operating portion is movably connected to the body portion. The operating portion is provided with a buckle portion. Thereby, the actuator may be arranged on an object and the operating portion allows the buckle portion to be buckled to or unbuckled from another object to complete rapid combination and separation of at least two objects, thereby achieving the effect of rapid combination and separation.

### CROSS-REFERENCE TO RELATED APPLICATION

This non-provisional application claims priority under 35 U.S. C. § 119(a) on Patent Application No(s). 113137572 filed in Taiwan, R.O.C. on Oct. 1, 2024, the entire contents of which are hereby incorporated by reference.

### BACKGROUND OF THE INVENTION

### 1. Field of the Invention

The present disclosure relates to a buckling structure, and in particular, to a buckling structure that can be used for repeatedly and rapidly combining and separating at least two objects.

### 2. Description of the Related Art

In general cases, screws are usually used for locking at least objects together.

In the conventional fixing method described above, although the at least objects are fixedly combined in such a way that they cannot be separated easily, they are not assembled easily, and they are not easily disassembled because of the fixed combination method using the screws.

In view of the prior art described above, the inventors have developed a buckling structure and a buckling method thereof, in which an actuator may be arranged on an object and an operating portion allows a buckle portion to be buckled to or unbuckled from another object to complete rapid combination and separation of at least two objects, thereby achieving the effect of rapid combination and separation.

### BRIEF SUMMARY OF THE INVENTION

In the buckling structure and the buckling method thereof according to the present disclosure, an actuator may be arranged on an object and an operating portion allows a buckle portion to be buckled to or unbuckled from another object to complete rapid combination and separation of at least two objects, thereby achieving the effect of rapid combination and separation.

In order to achieve the above objective or other objectives, the present disclosure provides a buckling structure, including: an intermediary and one actuator or two actuators. The actuator is movably or fixedly arranged on the intermediary. The actuators each include a body portion and an operating portion. The operating portion is movably connected to the body portion, or the operating portion is provided with a buckle portion, or the actuator is used in combination with another buckle portion or another object to limit the intermediary.

Optionally, the intermediary is a handle, a handle pulling body, a plate body, a circuit board, a casing body, a metal body, a plastic body, a buckle body, a limiting body, a heating body or a radiating body; or the intermediary is a radiating body configured to dissipate heat for the heating body.

Optionally, the intermediary is provided with a hole portion, a slot portion or a corresponding structure, configured to limit the intermediary between each of the body portions and each of the operating portions.

Optionally, the buckling structure further includes at least one elastic component or two elastic components. The elastic component is arranged between the operating portion and the body portion, or the elastic component is arranged between the body portion and the intermediary, or the elastic component is arranged between the operating portion and the intermediary, or each of the elastic components is arranged between each of the operating portions and each of the body portions, or each of the elastic components is arranged between each of the body portions and the intermediary, or each of the elastic components is arranged between each of the operating portions and the intermediary.

Optionally, each of the body portions is configured to be welded, riveted, flare-fitted, locked or buckled to an object.

Optionally, each of the buckle portions is a thread body, a screw, a nut, an external buckle body, an internal buckle body, a column body, an elastic buckle body or a buckle portion, such that each of the buckle portions is buckled to the other object.

Optionally, each of the actuators is capable of being connected to an object at the same time, or each of the actuators is capable of being welded to the object at the same time, or each of the actuators is capable of being riveted to the object at the same time, or each of the actuators is capable of being flare-fitted to the object at the same time, or each of the actuators is capable of being locked to the object at the same time, or each of the actuators is capable of being buckled to the object at the same time, where each of the actuators is capable of being connected to the object at different times or respectively by different processes, or each of the actuators is capable of being welded to the object at different times or respectively by different processes, or each of the actuators is capable of being riveted to the object at different times or respectively by different processes, or each of the actuators is capable of being flare-fitted to the object at different times or respectively by different processes, or each of the actuators is capable of being locked to the object at different times or respectively by different processes, or each of the actuators is capable of being buckled to the object at different times or respectively by different processes.

Optionally, one of the actuators is capable of being connected to the object first, and the other actuator is then connected to the object or the other object.

Optionally, the buckling structure further includes at least two elastic components. Each of the elastic components normally abuts against each of the body portions and the intermediary to allow the intermediary to be normally located in a descending position or normally located in an ascending position.

Optionally, the intermediary, each of the body portions or each of the operating portions is provided with a storage space. The storage space is configured to store at least one elastic component, or the storage space is configured to store at least one compressed elastic component.

Optionally, a number of the intermediaries is one or more, and a number of the actuators is two or more.

Optionally, each of the operating portions is movably assembled, fixedly assembled or integrally formed to each of the body portions.

Optionally, one of the body portions or both of the body portions is/are provided with an anti-rotation portion, configured to limit positions or directions of the body portion and an object, or configured to limit a position or direction of the operating portion, or configured to limit a position or direction of the buckle portion, or configured to limit the positions or directions of the operating portion and the body portion, or configured to limit the positions or directions of the buckle portion and the body portion, or configured to limit the positions or directions of the operating portion and the object, or configured to limit the positions or directions of the buckle portion and the object.

Optionally, the buckling structure further includes an elastic component. The elastic component abuts against the actuator and the intermediary. The intermediary presses or abuts against an object or a heating body, or a height of the object or the heating body is greater than a distance between the body portion and the intermediary so as to obtain an elastic height or allow an elastic force of the elastic component to press or abut against the object or the heating body through the intermediary, or the intermediary is a radiating body.

Optionally, the actuator is buckled to an object with the buckle portion, or the buckle portion is configured to be buckled to a buckled portion of the object.

Optionally, after being buckled to the buckled portion, the buckle portion is parallel to the object to reduce a height between the intermediary and the object, or the buckle portion is parallel to the object to reduce the height between the intermediary and the object or parallel to the buckled portion to reduce the height between the intermediary and the object, or the buckle portion is parallel to the buckled portion to reduce the height between the intermediary and the object or lower than the object to reduce the height between the intermediary and the object, or the buckle portion is lower than the object to reduce the height between the intermediary and the object, or the buckle portion is higher than the object after being buckled to the buckled portion to reduce the height between the intermediary and the object or higher than the object after being buckled to the buckled portion to reduce the height between the intermediary and the object.

Optionally, the buckle portion or the buckled portion is an external thread body, a column body, an internal thread body, an elastic buckle body, an external buckle body or an internal buckle body.

Optionally, the buckle portion has an accommodating portion configured to accommodate the buckled portion to reduce or lower a height or a distance between the intermediary and the object, or the accommodating portion is an internal thread portion, a hole portion, a slot portion or a recess portion.

Optionally, the body portion is arranged or connected to the intermediary.

The present disclosure further provides a buckling method of a buckling structure. The buckling structure includes an intermediary and one actuator or two actuators. Each of the actuators is movably or fixedly arranged on the intermediary respectively. Each of the actuators respectively includes a body portion or an operating portion, or each of the operating portions is movably connected to each of the body portions, or each of the operating portions is provided with a buckle portion. One of the body portions or both of the body portions is/are provided with an anti-rotation portion, configured to limit positions or directions of the body portion and an object, or configured to limit a position or direction of the operating portion, or configured to limit a position or direction of the buckle portion, or configured to limit the positions or directions of the operating portion and the body portion, or configured to limit the positions or directions of the buckle portion and the body portion, or configured to limit the positions or directions of the operating portion and the object, or configured to limit the positions or directions of the buckle portion and the object.

The present disclosure further provides a buckling method of a buckling structure. The buckling structure includes an intermediary and one actuator or two actuators. Each of the actuators is movably or fixedly arranged on the intermediary respectively. Each of the actuators respectively includes a body portion or an operating portion, or each of the operating portions is movably connected to each of the body portions, or each of the operating portions is provided with a buckle portion, or the intermediary is a handle, a handle pulling body, a buckle body, a limiting body or a radiating body, or the intermediary is a radiating body configured to dissipate heat for the heating body, or the intermediary is provided with a hole portion, a slot portion or a corresponding structure configured to limit the intermediary between each of the body portions and each of the operating portions, or the buckling structure further includes at least two elastic components. Each of the elastic components is arranged between each of the operating portions and each of the body portions, or each of the elastic components is arranged between each of the body portions and the intermediary, or each of the elastic components is arranged between each of the operating portions and the intermediary, or each of the buckle portions is a thread body, a screw, a nut, an external buckle body, an internal buckle body, a column body, an elastic buckle body or a buckle portion, such that each of the buckle portions is buckled to another object.

The present disclosure further provides a buckling method of a buckling structure. The buckling structure includes an intermediary and one actuator or two actuators. Each of the actuators is movably or fixedly arranged on the intermediary respectively. Each of the actuators respectively includes a body portion or an operating portion, or each of the operating portions is movably connected to each of the body portions, or each of the operating portions is provided with a buckle portion. Each of the actuators is capable of being connected to an object at the same time, or each of the actuators is capable of being welded to the object at the same time, or each of the actuators is capable of being riveted to the object at the same time, or each of the actuators is capable of being flare-fitted to the object at the same time, or each of the actuators is capable of being locked to the object at the same time, or each of the actuators is capable of being buckled to the object at the same time. Each of the actuators is capable of being connected to the object at different times or respectively by different processes, or each of the actuators is capable of being welded to the object at different times or respectively by different processes, or each of the actuators is capable of being riveted to the object at different times or respectively by different processes, or each of the actuators is capable of being flare-fitted to the object at different times or respectively by different processes, or each of the actuators is capable of being locked to the object at different times or respectively by different processes, or each of the actuators is capable of being buckled to the object at different times or respectively by different processes, or one of the actuators is capable of being connected to the object first, and the other actuator is then connected to the object or another object.

The present disclosure further provides a buckling method of a buckling structure. The buckling structure includes an intermediary and one actuator or two actuators. Each of the actuators is movably or fixedly arranged on the intermediary respectively. Each of the actuators respectively includes a body portion or an operating portion, or each of the operating portions is movably connected to each of the body portions, or each of the operating portions is provided with a buckle portion. Or the buckling structure further includes at least two elastic components. Each of the elastic components normally abuts against each of the body portions and the intermediary to allow the intermediary to be normally located in a descending position or normally located in an ascending position. Or the intermediary, each of the body portions or each of the operating portions is provided with a storage space. The storage space is configured to store at least one elastic component, or the storage space is configured to store at least one compressed elastic component. Or a number of the intermediaries is one or more, or a number of the actuators is two or more. Or each of the operating portions is movably assembled, fixedly assembled or integrally formed to each of the body portions.

The present disclosure further provides a buckling method of a buckling structure. The buckling structure includes an intermediary and one actuator or two actuators. Each of the actuators is movably or fixedly arranged on the intermediary respectively. Each of the actuators respectively includes a body portion or an operating portion, or each of the operating portions is movably connected to each of the body portions, or each of the operating portions is provided with a buckle portion, or the buckling structure further includes an elastic component. The elastic component abuts against the actuator and the intermediary. The intermediary presses or abuts against an object or a heating body, or a height of the object or the heating body is greater than a distance between the body portion and the intermediary so as to obtain an elastic height or allow an elastic force of the elastic component to press or abut against the object or the heating body through the intermediary, or the intermediary is a radiating body.

The present disclosure further provides a buckling method of a buckling structure. The buckling structure includes an intermediary and at least one actuator or two actuators, or the actuator has a buckle portion, or the actuator is buckled to an object with the buckle portion, or the buckle portion is configured to be buckled to a buckled portion of the object. After being buckled to the buckled portion, the buckle portion is parallel to the object to reduce a height between the intermediary and the object, or the buckle portion is parallel to the object to reduce the height between the intermediary and the object or parallel to the buckled portion to reduce the height between the intermediary and the object, or the buckle portion is parallel to the buckled portion to reduce the height between the intermediary and the object or lower than the object to reduce the height between the intermediary and the object, or the buckle portion is lower than the object to reduce the height between the intermediary and the object, or the buckle portion is higher than the object after being buckled to the buckled portion to reduce the height between the intermediary and the object or higher than the object after being buckled to the buckled portion to reduce the height between the intermediary and the object. Or the buckle portion or the buckled portion is an external thread body, a column body, an internal thread body, an elastic buckle body, an external buckle body or an internal buckle body. Or the buckle portion has an accommodating portion configured to accommodate the buckled portion to reduce or lower a height or a distance between the intermediary and the object, or the accommodating portion is an internal thread portion, a hole portion, a slot portion or a recess portion, or the body portion is arranged or connected to the intermediary.

### BRIEF DESCRIPTION OF THE DRAWINGS

FIG. 1 is a schematic view of a first embodiment of the present disclosure in use.

FIG. 2 is a schematic top view of the first embodiment of the present disclosure.

FIG. 3 is a schematic view of a second embodiment of the present disclosure.

FIG. 4 is a schematic view of a third embodiment of the present disclosure.

FIG. 5 is a schematic view of a fourth embodiment of the present disclosure.

FIG. 6 is a schematic view of a fifth embodiment of the present disclosure.

FIG. 7 is a schematic view of a sixth embodiment of the present disclosure.

FIG. 8 is a schematic view of a seventh embodiment of the present disclosure.

FIG. 9 is a schematic view of an eighth embodiment of the present disclosure.

FIG. 10 is a schematic view of a ninth embodiment of the present disclosure.

FIG. 11 is a schematic view of a tenth embodiment of the present disclosure.

FIG. 12 is a schematic view of an eleventh embodiment of the present disclosure.

FIG. 13 is a schematic view of a twelfth embodiment of the present disclosure.

FIG. 14 is a schematic view of a thirteenth embodiment of the present disclosure.

FIG. 15 is a schematic view of a fourteenth embodiment of the present disclosure.

FIG. 16 is a schematic view of a fifteenth embodiment of the present disclosure.

FIG. 17 is a schematic view of a sixteenth embodiment of the present disclosure.

FIG. 18 is a schematic view of a buckle portion and a buckled portion in different shapes in the present disclosure.

FIG. 19 is a schematic view of a seventeenth embodiment of the present disclosure.

FIG. 20 is a schematic view of an eighteenth embodiment of the present disclosure.

FIG. 21 is a schematic view of a nineteenth embodiment of the present disclosure.

### DETAILED DESCRIPTION OF THE INVENTION

The buckling structure of embodiments of the present disclosure will be further described below with reference to the accompanying drawings.

The foregoing and other technical contents, features and effects of the present disclosure will be clearly presented in the following detailed description of preferred embodiments with reference to the accompanying drawings. It is worth mentioning that the direction terms mentioned in the embodiments below, such as up, down, left, right, front or rear, etc., are only directions referring to the accompanying drawings. Therefore, the direction terms used are intended to illustrate rather than limit the present disclosure. In addition, in the following embodiments, the same or similar components will use the same or similar reference numerals.

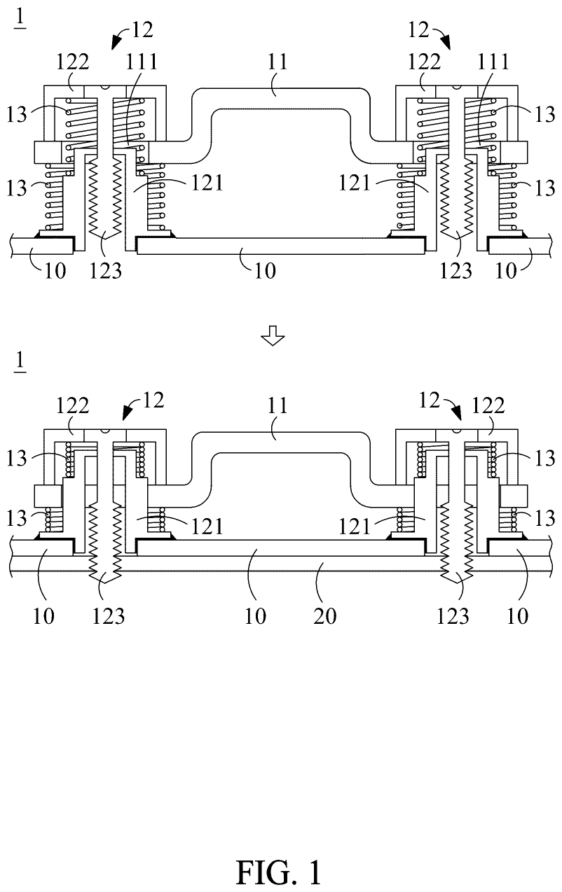

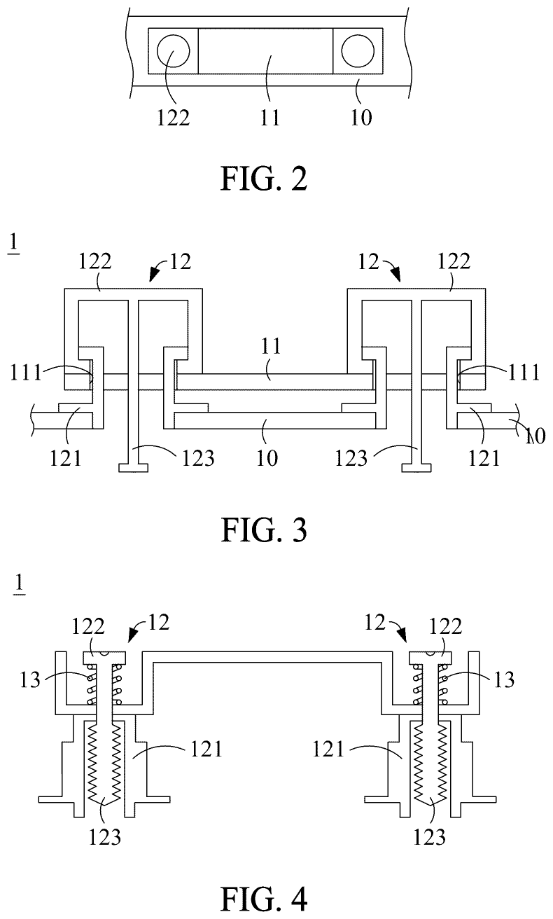

Referring to FIG. 1 and FIG. 2, the present disclosure provides a buckling structure and a buckling method thereof. The buckling structure 1 includes an intermediary 11 and one actuator 12 or at least two actuators 12 (two actuators 12 are shown in the figures of this embodiment).

Each of the actuators 12 is movably or fixedly arranged on the intermediary 1. Each of the actuators 12 respectively includes a body portion 121 and an operating portion 122. Each of the operating portions 122 is movably connected to each of the body portions 121, or each of the operating portions 122 is provided with a buckle portion 123.

When in use, the buckling structure 1 may be connected to an object 10 with the body portion 11. In this embodiment, each of the actuators 12 is capable of being connected to the object 10 at the same time and exerting a force to each of the operating portions 122, such that each of the operating portions 122 drives each of the buckle portions 123 to be buckled to another object 20, and thereby, each of the buckle portions 123 can be buckled to the other object 20 (or moved in an opposite direction to be unbuckled from the other object 20). In this way, each of the actuators 12 may be arranged on the object 10, and each of the operating portions 122 drives the buckle portion 123 to be buckled to or unbuckled from the other object 20 to complete rapid combination and separation of at least two objects, thereby achieving the effect of rapid combination and separation.

After the buckling structure 1 is buckled to the other object 20 with each of the actuators 12, a force may be exerted to the intermediary 11 so as to move the object 10 and the other object 20.

In addition to the above embodiment, in an embodiment of the present disclosure, the intermediary 11 may be a handle, a handle pulling body, a plate body, a circuit board, a casing body, a metal body, a plastic body, a buckle body or a limiting body or be configured to limit a heating body. In this way, a force may be exerted to the intermediary 11 so as to move the object 10 and the other object 20.

In addition to the above embodiment, in an embodiment of the present disclosure, the intermediary 11 is provided with a hole portion 111 (or a slot portion or a corresponding structure) configured to limit the intermediary 11 between each of the body portions 11 and each of the operating portions 122.

In addition to the above embodiment, in an embodiment of the present disclosure, the buckling structure further includes at least two elastic components 13 (such as compression springs). In this embodiment, there are four elastic components 13. Two of the elastic components 13 are arranged between each of the operating portions 122 and each of the body portions 121, and the other two elastic components 13 are arranged between each of the body portions 121 and the intermediary 11. In this way, each of the elastic components 13 may be used for allowing the buckle portion 123 of each of the actuators 12 to be normally located in an unbuckled state, or the elastic component 13 may be used for allowing the buckle portion 123 of each of the actuators 12 to be normally located in a buckled state.

In addition to the above embodiment, in an embodiment of the present disclosure, the body portion 121 of each of the actuators 12 may be combined to the object 10 by welding, riveting, flare-fitting, locking or buckling. In this way, each of the actuators 12 can be firmly combined with the object 10.

In addition to the above embodiment, in an embodiment of the present disclosure, each of the buckle portions 123 is a thread body, a screw, a nut, an external buckle body, an internal buckle body, a column body, an elastic buckle body or a buckle portion, such that each of the buckle portions 123 is buckled to the other object 20 according to actual needs.

In addition to the above embodiment, in an embodiment of the present disclosure, each of the actuators 12 is capable of being welded to the object 10 at the same time (at different times or respectively by different processes), or each of the actuators 12 is capable of being riveted to the object 10 at the same time (at different times or respectively by different processes), or each of the actuators 12 is capable of being flare-fitted to the object 10 at the same time (at different times or respectively by different processes), or each of the actuators 12 is capable of being locked to the object 10 at the same time (at different times or respectively by different processes), or each of the actuators 12 is capable of being buckled to the object 10 at the same time. In addition, one of the actuators 12 is capable of being connected to the object 10 first, and the other actuator 12 is then connected to the object 10 or the other object 20. In this way, each of the actuators 12 can be firmly combined with the object 10 or the other object 20.

Referring to FIG. 3, in addition to the above embodiment, in an embodiment of the present disclosure, the buckling structure 1 may not be provided with an elastic component 13. In this way, the buckling structure 1 can be made more complying with the requirements of practical use.

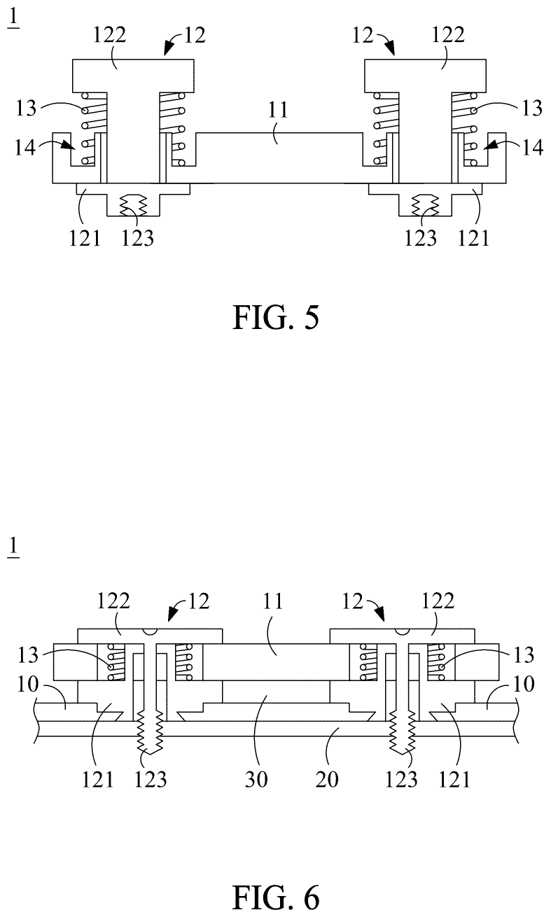

Referring to FIG. 4 and FIG. 5, in addition to the above embodiment, in an embodiment of the present disclosure, each of the operating portions 122 of each of the actuators 12 is movably assembled to each of the body portions 12 (as shown in FIG. 4), or each of the operating portion 122 is fixedly assembled or integrally formed to each of the body portions 12 (as shown in FIG. 5). Moreover, each of the elastic components 13 is arranged between each of the operating portions 122 and the intermediary 11. Moreover, the intermediary 11 is provided with at least one storage space 14. Each of the storage spaces 14 is configured to store each of the elastic components 13, and each of the storage spaces 14 is configured to store each of the compressed elastic components 13. In this way, each of the storage spaces 14 can be used for maintaining the stability of each of the elastic components 13 during actuation.

Referring to FIG. 6, in addition to the above embodiment, in an embodiment of the present disclosure, the intermediary 11 may be a radiating body (or a limiting body), such that the intermediary 11 is configured to limit the heating body 30 and the intermediary 11 is configured to dissipate heat for the heating body 30. In this way, the buckling structure 1 can be made more complying with the requirements of practical use.

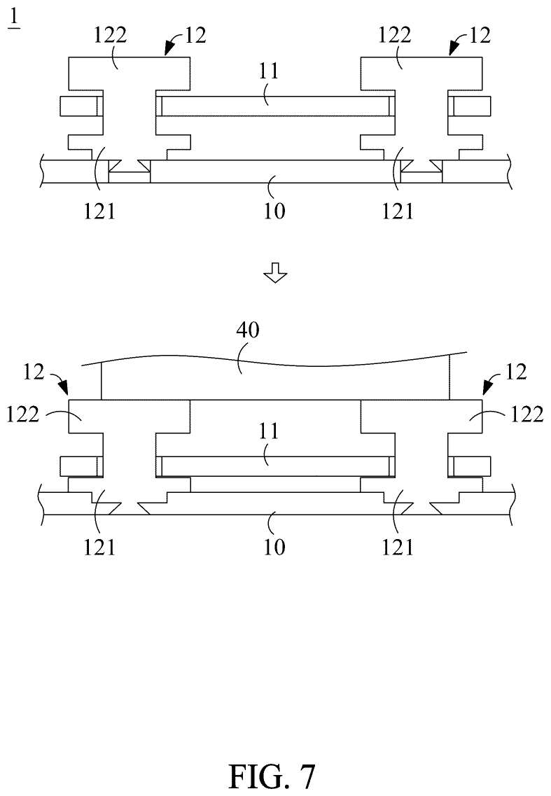

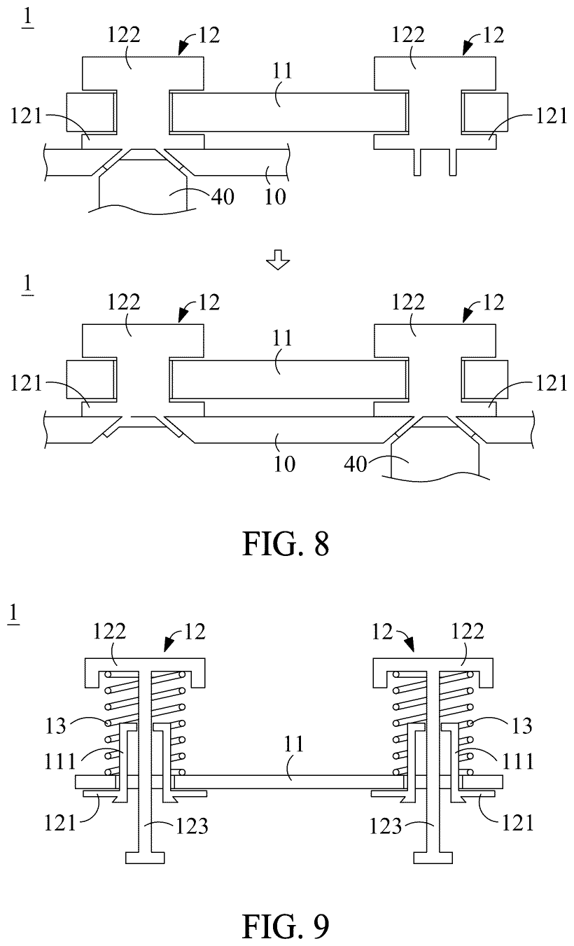

Referring to FIG. 7 and FIG. 8, in addition to the above embodiment, in an embodiment of the present disclosure, each of the operating portions 122 of each of the actuators 12 is fixedly assembled or integrally formed with each of the body portions 12, and each of the actuators 12 may be riveted to the object 10 at the same time (at different times or respectively by different processes) by using a mold 40 (as shown in FIG. 7), or each of the actuators 12 may be flare-fitted to the object 10 respectively (at the same time or by different processes) by using a mold 40 (as shown in FIG. 8). In this way, the buckling structure 1 can be made more complying with the requirements of practical use.

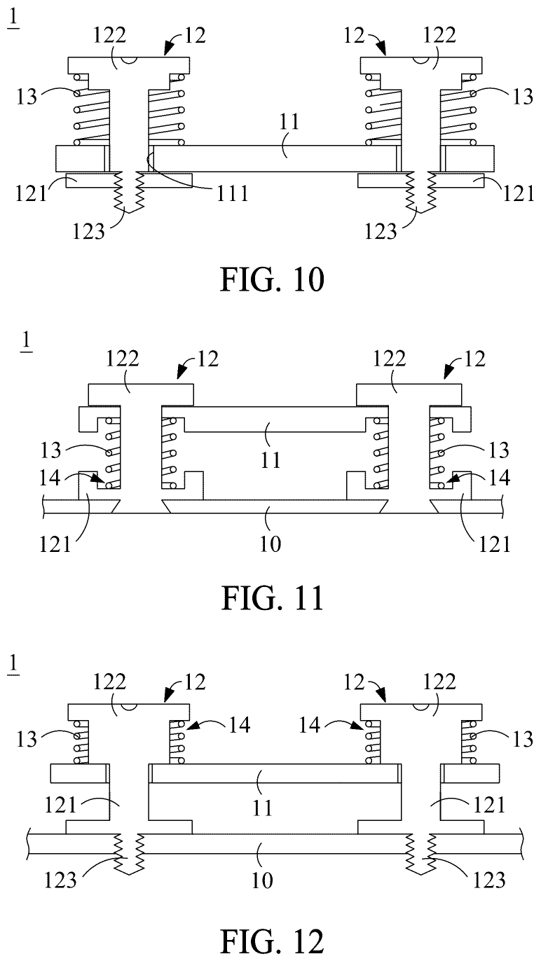

Referring to FIG. 9 and FIG. 10, in addition to the above embodiment, in an embodiment of the present disclosure, each of the operating portions 122 of each of the actuators 12 is movably assembled to each of the body portions 12 (as shown in FIG. 9), or each of the operating portions 122 is fixedly assembled or integrally formed to each of the body portions 12 (as shown in FIG. 10). Each of the elastic components 13 is arranged between each of the operating portions 122 and the intermediary 11, and each of the elastic components 13 normally abuts against each of the operating portions 122 and the intermediary 11, or is configured to allow the intermediary 11 to be normally located in a descending position. In this way, each of the actuators 12 may also be arranged on the object 10 and exert a force to each of the operating portions 122 to compress each of the elastic components 13, such that each of the operating portions 122 drives each of the buckle portions 123 to be buckled to or unbuckled from the other object 20 to complete rapid combination and separation of at least two objects, thereby achieving the effect of rapid combination and separation.

Referring to FIG. 11 and FIG. 12, in addition to the above embodiment, in an embodiment of the present disclosure, each of the operating portions 122 of each of the actuators 12 is fixedly assembled or integrally formed to each of the body portions 12, each of the elastic components 13 is arranged between each of the body portions 121 and the intermediary 11, and each of the body portions 121 is provided with a storage space 14 (as shown in FIG. 11); or each of the elastic components 13 is arranged between each of the operating portions 122 and the intermediary 11, each of the operating portions 122 is provided with a storage space 14 (as shown in FIG. 12), each of the storage spaces 14 is configured to store each of the elastic components 13, each of the storage spaces 14 is configured to store each of the compressed elastic components 13, and each of the elastic components 13 normally abuts against each of the body portions 121 and the intermediary 11 to allow the intermediary 11 to be normally located in an ascending position (as shown in FIG. 12). In this way, each of the storage spaces 14 can be used for maintaining the stability of each of the elastic components 13 during actuation.

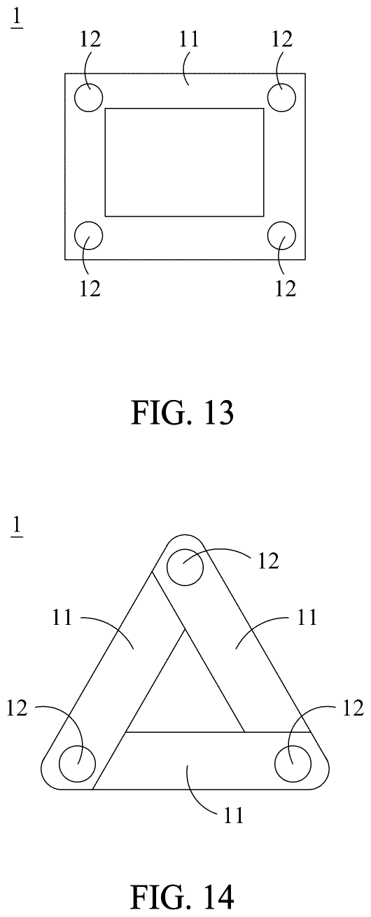

Referring to FIG. 13 and FIG. 14, in addition to the above embodiment, in an embodiment of the present disclosure, a number of the intermediaries 11 is one or more, or a number of the actuators 12 is two or more. For example, the number of the intermediaries 11 may be one and the number of the actuators 12 may be four or more (as shown in FIG. 13), or the number of the intermediaries 11 may be three and the number of the actuators 12 may be three or more (as shown in FIG. 14). In this way, the buckling structure 1 can be made more complying with the requirements of practical use.

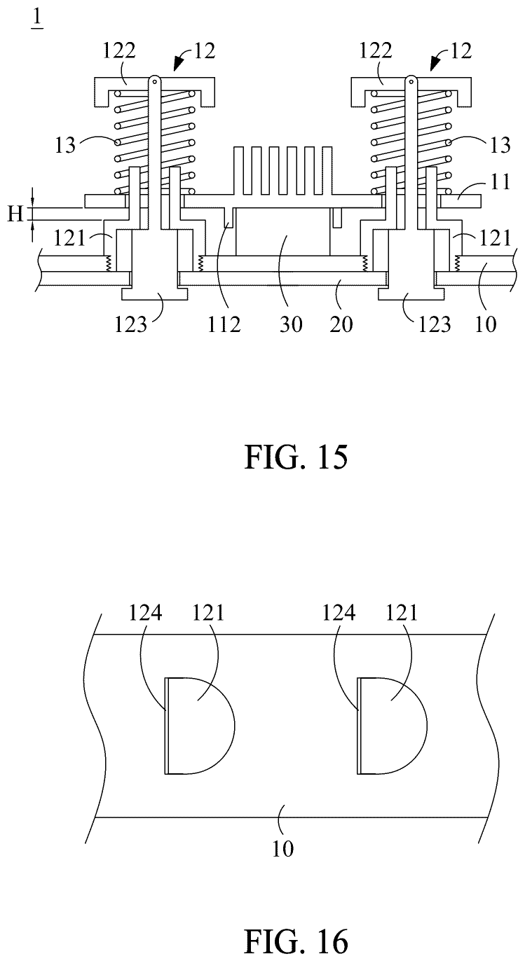

Referring to FIG. 15, in addition to the above embodiment, in an embodiment of the present disclosure, the intermediary 11 may be a radiating body (or a limiting body), the elastic component 13 abuts against the actuator 12 and the intermediary 11, the intermediary 11 presses (or abuts) against the heating body 30 (or the object 10), and a height of the heating body 30 (or the object 10) is greater than a distance between the body portion 121 and the intermediary 11 so as to obtain an elastic height H or allow an elastic force of the elastic component 13 to press (or abut) against the heating body 30 (or the object 10) through the intermediary 11. The intermediary 11 limits the heating body 30 with a buckle member 112 at a bottom thereof, such that the intermediary 11 abuts against the heating body 30 and the intermediary 11 is configured to dissipate heat for the heating body 30. In this way, the buckling structure 1 can be made more complying with the requirements of practical use.

Referring to FIG. 16, in addition to the above embodiment, in an embodiment of the present disclosure, both of the two body portions 121 (or one of the body portions 121) may be respectively provided with an anti-rotation portion 124. The anti-rotation portion 124 may be configured to limit positions (or directions) of the body portion 121 and the object 10, or the anti-rotation portion 124 may be configured to limit a position (or direction) of the operating portion 122, or the anti-rotation portion 124 may be configured to limit a position (or direction) of the buckle portion 123, or the anti-rotation portion 124 may be configured to limit the positions (or directions) of the operating portion 122 and the body portion 121, or the anti-rotation portion 124 may be configured to limit the positions (or directions) of the buckle portion 123 and the body portion 121, or the anti-rotation portion 124 may be configured to limit the positions (or directions) of the operating portion 122 and the object 10, or the anti-rotation portion 124 may be configured to limit the positions (or directions) of the buckle portion 123 and the object 10. In this way, the buckling structure 1 can be made more complying with the requirements of practical use.

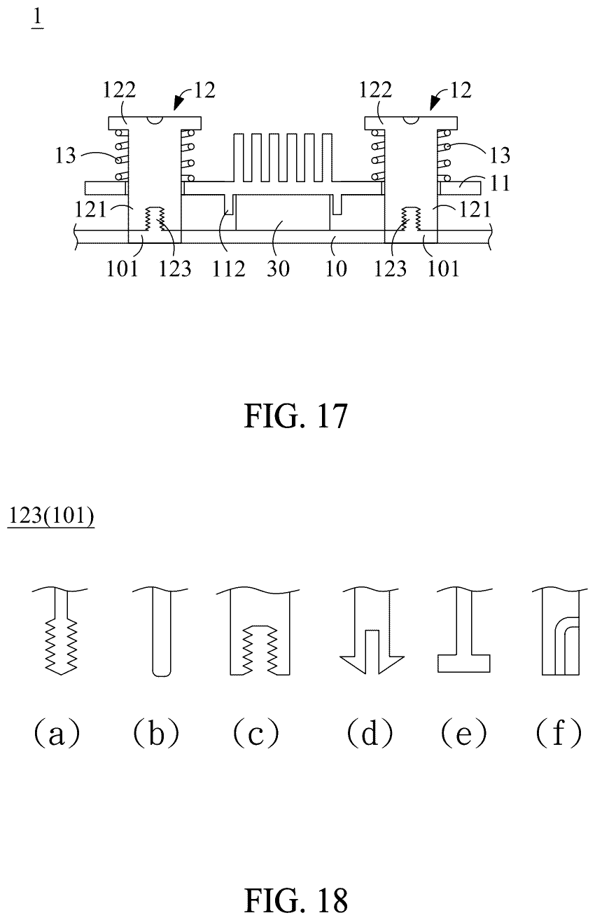

Referring to FIG. 17 and FIG. 18, in addition to the above embodiment, in an embodiment of the present disclosure, the actuator 12 is buckled to an object 10 with the buckle portion 123, or the buckle portion 123 is configured to be buckled to a buckled portion 101 of the object 10. In this way, the buckling structure 1 can be made more complying with the requirements of practical use.

In an embodiment of the present disclosure, the buckle portion 123 or the buckled portion 101 may be an external thread body (part a in FIG. 18), a column body (part b in FIG. 18), an internal thread body (part c in FIG. 18), an elastic buckle body (part d in FIG. 18), an external buckle body (part e in FIG. 18) or an internal buckle body (part f in FIG. 18). In this way, the buckling structure 1 can be made more complying with the requirements of practical use.

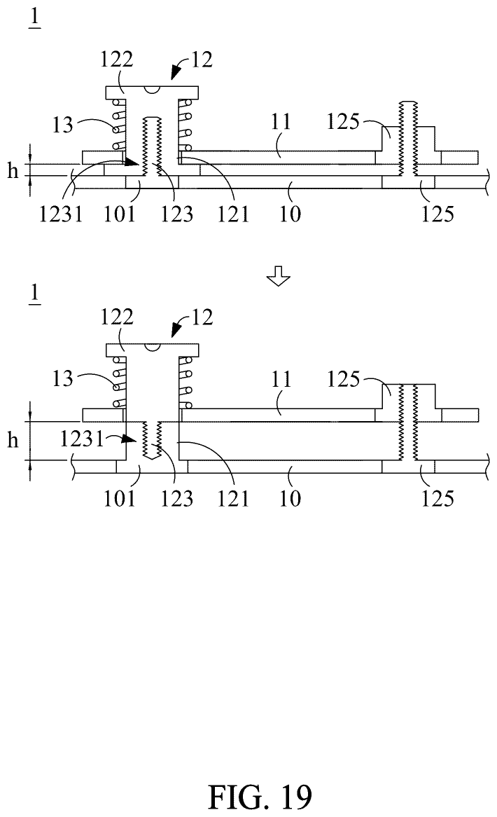

Referring to FIG. 19, in an embodiment of the present disclosure, the actuator 12 is used in combination with another buckle portion 125 (or another object) to limit the intermediary 11, and after being buckled to the buckled portion 101, the buckle portion 123 is parallel to the object 10 or lower than the object 10 to reduce a height h between the intermediary 11 and the object 10, or after being buckled to the buckled portion 101, the buckle portion 123 is higher than the object 10. In this way, the buckling structure 1 can be made more complying with the requirements of practical use.

In an embodiment of the present disclosure, after being buckled to the buckled portion 101, the buckle portion 123 is parallel to the object 10 to reduce a height between the intermediary 11 and the object 10, or the buckle portion 123 is parallel to the object 10 to reduce the height between the intermediary 11 and the object 10 or parallel to the buckled portion 101 to reduce the height between the intermediary 11 and the object 10, or the buckle portion 123 is parallel to the buckled portion 101 to reduce the height between the intermediary 11 and the object 10 or lower than the object 10 to reduce the height between the intermediary 11 and the object 10, or the buckle portion 123 is lower than the object 10 to reduce the height between the intermediary 11 and the object 10, or the buckle portion 123 is higher than the object 10 after being buckled to the buckled portion 101 to reduce the height between the intermediary 11 and the object 10 or higher than the object 10 after being buckled to the buckled portion 101 to reduce the height between the intermediary 11 and the object 10. In this way, the buckling structure 1 can be made more complying with the requirements of practical use.

In an embodiment of the present disclosure, the buckle portion 123 has an accommodating portion 1231 configured to accommodate the buckled portion 101 to reduce or lower a height h (or a distance) between the intermediary 11 and the object 10, and the accommodating portion 1231 may be an internal thread portion, a hole portion, a slot portion or a recess portion. In this way, the buckling structure 1 can be made more complying with the requirements of practical use.

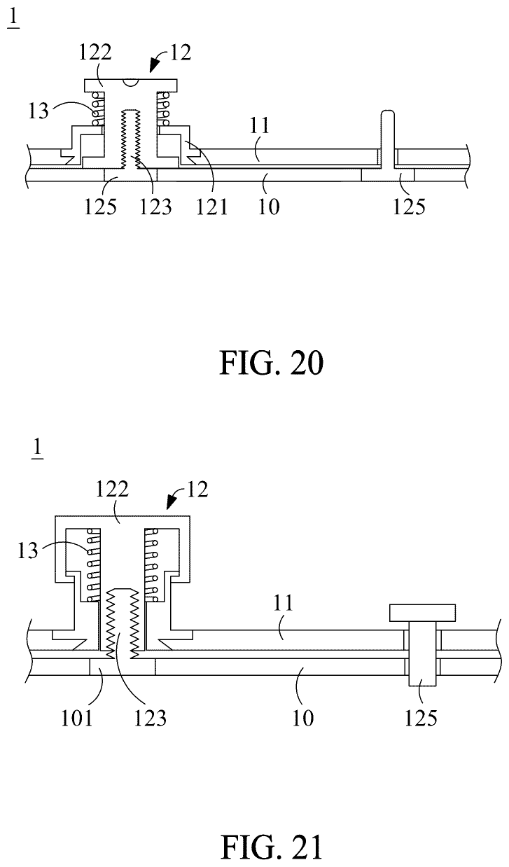

Referring to FIG. 20 and FIG. 21, in an embodiment of the present disclosure, the body portion 121 is arranged or connected to the intermediary 11. In this way, the buckling structure 1 can be made more complying with the requirements of practical use.

Based on the above, according to the buckling structure and the buckling method thereof in the present disclosure, the actuator may be arranged on the object and the operating portion allows the buckle portion to be buckled to or unbuckled from the other object to complete rapid combination and separation of at least two objects, thereby achieving the effect of rapid combination and separation.

The above is only embodiments of the present disclosure, and it is not intended to limit the scope of the present disclosure.

What is claimed is:

1. A buckling structure, comprising:
an intermediary; and
one actuator or two actuators, movably or fixedly arranged on the intermediary, or the actuator comprising a body portion or an operating portion, or the operating portion being movably connected to the body portion, or the operating portion having a buckle portion, or the actuator being used in combination with another buckle portion or another object to limit the intermediary.

2. The buckling structure according to claim 1, wherein the intermediary is a handle, a handle pulling body, a plate body, a circuit board, a casing body, a metal body, a plastic body, a buckle body, a limiting body, a heating body or a radiating body; or the intermediary is a radiating body configured to dissipate heat for the heating body; or the intermediary is provided with a hole portion, a slot portion or a corresponding structure, or configured to limit the intermediary between each of the body portions and each of the operating portions.

3. The buckling structure according to claim 1, further comprising one elastic component or at least two elastic components, wherein the elastic component is arranged between the operating portion and the body portion, or the elastic component is arranged between the body portion and the intermediary, or the elastic component is arranged between the operating portion and the intermediary, or each of the elastic components is arranged between each of the operating portions and each of the body portions, or each of the elastic components is arranged between each of the body portions and the intermediary, or each of the elastic components is arranged between each of the operating portions and the intermediary.

4. The buckling structure according to claim 1, wherein each of the body portions is configured to be welded, riveted, flare-fitted, locked or buckled to an object; or each of the buckle portions is a thread body, a screw, a nut, an external buckle body, an internal buckle body, a column body, an elastic buckle body or a buckle portion, such that each of the buckle portions is buckled to the other object.

5. The buckling structure according to claim 1, wherein each of the actuators is capable of being connected to an object at the same time, or each of the actuators is capable of being welded to the object at the same time, or each of the actuators is capable of being riveted to the object at the same time, or each of the actuators is capable of being flare-fitted to the object at the same time, or each of the actuators is capable of being locked to the object at the same time, or each of the actuators is capable of being buckled to the object at the same time, or wherein each of the actuators is capable of being connected to the object at different times or respectively by different processes, or each of the actuators is capable of being welded to the object at different times or respectively by different processes, or each of the actuators is capable of being riveted to the object at different times or respectively by different processes, or each of the actuators is capable of being flare-fitted to the object at different times or respectively by different processes, or each of the actuators is capable of being locked to the object at different times or respectively by different processes, or each of the actuators is capable of being buckled to the object at different times or respectively by different processes; or one of the actuators is capable of being connected to the object first, and the other actuator is then connected to the object or the other object.

6. The buckling structure according to claim 1, further comprising at least two elastic components, wherein each of the elastic components normally abuts against each of the body portions and the intermediary to allow the intermediary to be normally located in a descending position or normally located in an ascending position; or the intermediary, each of the body portions or each of the operating portions is provided with a storage space; the storage space is configured to store at least one elastic component, or the storage space is configured to store at least one compressed elastic component; or a number of the intermediaries is one or more, or a number of the actuators is two or more; or each of the operating portions is movably assembled, fixedly assembled or integrally formed to each of the body portions.

7. The buckling structure according to claim 1, wherein one of the body portions or both of the body portions is/are provided with an anti-rotation portion, configured to limit positions or directions of the body portion and an object, or configured to limit a position or direction of the operating portion, or configured to limit a position or direction of the buckle portion, or configured to limit the positions or directions of the operating portion and the body portion, or configured to limit the positions or directions of the buckle portion and the body portion, or configured to limit the positions or directions of the operating portion and the object, or configured to limit the positions or directions of the buckle portion and the object.

8. The buckling structure according to claim 1, further comprising an elastic component, wherein the elastic component abuts against the actuator and the intermediary, the intermediary presses or abuts against an object or a heating body, or a height of the object or the heating body is greater than a distance between the body portion and the intermediary so as to obtain an elastic height or allow an elastic force of the elastic component to press or abut against the object or the heating body through the intermediary, or the intermediary is a radiating body; or the body portion is arranged or connected to the intermediary.

9. The buckling structure according to claim 1, wherein the actuator is buckled to an object with the buckle portion, or the buckle portion is configured to be buckled to a buckled portion of the object; or after being buckled to the buckled portion, the buckle portion is parallel to the object to reduce a height between the intermediary and the object, or the buckle portion is parallel to the object to reduce the height between the intermediary and the object or parallel to the buckled portion to reduce the height between the intermediary and the object, or the buckle portion is parallel to the buckled portion to reduce the height between the intermediary and the object or lower than the object to reduce the height between the intermediary and the object, or the buckle portion is lower than the object to reduce the height between the intermediary and the object, or the buckle portion is higher than the object after being buckled to the buckled portion to reduce the height between the intermediary and the object or higher than the object after being buckled to the buckled portion to reduce the height between the intermediary and the object or the buckle portion or the buckled portion is an external thread body, a column body, an internal thread body, an elastic buckle body, an external buckle body or an internal buckle body; or the buckle portion has an accommodating portion configured to accommodate the buckled portion to reduce or lower a height or a distance between the intermediary and the object, or the accommodating portion is an internal thread portion, a hole portion, a slot portion or a recess portion.
